(19) United States
(12) Patent Application Publication
(10) Pub. No.: US 2026/0305145 A1
(43) Pub. Date: Oct. 1, 2026

(54) Display Device

(71) Applicant: LG Display Co., Ltd., Seoul (KR)

(72) Inventors: Hoyoon Jung, Paju-si (KR); Geonhyeong Kim, Paju-si (KR); Seongmin Yang, Paju-si (KR); Jiho Son, Paju-si (KR)

(21) Appl. No.: 19/565,970

(22) Filed: Mar. 13, 2026

(30) Foreign Application Priority Data
Mar. 27, 2025 (KR) 10-2025-0039363

(51) Int. Cl. H10K 59/80; H10K 59/35

(52) U.S. Cl. CPC H10K 59/8792; H10K 59/35

(57) ABSTRACT

Another embodiment of the present invention seek to provides a display device including a display panel having pixels; a cover substrate on the display panel; and an anti-glare layer on the cover substrate, wherein the anti-glare layer includes a plurality of concave portions and a plurality of convex portions that are alternately disposed, and the anti-glare layer has an arithmetic mean roughness (Ra) of 0.25 μm or less and an average width (Rsm) of 10 μm or less.

### CROSS-REFERENCE TO RELATED APPLICATIONS

This application claims the benefit of priority of Republic of Korea Patent Application No. 10-2025-0039363 filed on Mar. 27, 2025, which is hereby incorporated by reference as if fully set forth herein.

### BACKGROUND

### Field of the Invention

The present invention relates to a display device capable of preventing or suppressing a sparkling phenomenon caused by an internal light source by including an anti-glare layer.

### Discussion of the Related Art

An organic light emitting diode OLED displays are attracting attention as next-generation flat panel displays because they feature fast response times, low power consumption, and excellent viewing angles as self-luminous devices that do not require a separate light source. Furthermore, OLED displays offer the advantage of being easily adaptable to flexible displays.

The display device includes a display panel on which an image is displayed. Furthermore, a light-transmitting cover substrate is typically disposed on the display surface of the display panel. The cover substrate may be surface-treated to prevent glare.

To prevent glare from being perceived through the cover substrate, irregular micro-patterns may be formed on the cover substrate. When such irregular patterns are disposed, the irregularity or non-uniformity caused by a plurality of irregularly arranged patterns may cause a sparkling phenomenon when the light-emitting element emits light. The sparkling phenomenon may refer to a phenomenon in which internal light is scattered by the irregular micro-patterns, resulting in an irregular sparkle.

Meanwhile, sparkling phenomenon may be noticeable in displays with high resolution, which may cause problems with readability.

### SUMMARY

One embodiment of the present invention provides a display device that can effectively reduce or prevent the occurrence of a sparkling phenomenon by including an anti-glare layer.

One embodiment of the present invention provides a display device that can effectively reduce or prevent the occurrence of a sparkling phenomenon while having a high haze value by including an anti-glare layer.

One embodiment of the present invention for achieving the above-described technical problem provides a display device including a display panel having pixels; a cover substrate on the display panel; and an anti-glare layer on the cover substrate, wherein the anti-glare layer includes a plurality of concave portions and a plurality of convex portions that are alternately disposed, and the anti-glare layer has an arithmetic mean roughness (Ra) of 0.25 μm or less and an average width (Rsm) of 10 μm or less.

The pixel includes a plurality of sub-pixels having different light-emitting portions, and the light-emitting portions of the plurality of sub-pixels may each be formed in a circular shape in a plan view.

The plurality of sub-pixels include a first sub-pixel that emits red light, a second sub-pixel that emits green light, and a third sub-pixel that emits blue light, wherein the first sub-pixel includes a first light-emitting portion, the second sub-pixel includes a second light-emitting portion, and the third sub-pixel includes a third light-emitting portion, and the diameters of the first to third light-emitting portions may be different from each other.

The diameter of the third light emitting portion may be larger than the diameter of the second light emitting portion, and the diameter of the second light emitting portion may be larger than the diameter of the first light emitting portion.

The anti-glare layer may have a root mean square height (Sq) of 0.4 μm or less.

The anti-glare layer may have a maximum height (Sz) of 10.0 μm or less.

The anti-glare layer may have a root mean square gradient (Sdq) in the range of 0.15 to 0.30.

The anti-glare layer may have an arithmetic mean peak curvature (Spc) in the range of 0.5 to 3.0.

The anti-glare layer can cover the entire upper surface of the cover substrate.

It may further include a resin layer disposed between the anti-glare layer and the cover substrate.

The display panel may include an organic light-emitting element disposed on a substrate; an encapsulation portion disposed on the organic light-emitting element; a touch electrode disposed on the encapsulation portion; color filters disposed on the touch electrode; and a black matrix disposed on the touch electrode and between the color filters.

The organic light-emitting element includes a first electrode; a light-emitting layer disposed on the first electrode; and a second electrode disposed on the light-emitting layer, and further includes a bank layer disposed on the substrate and overlapping an edge of the first electrode, wherein the black matrix can overlap the touch electrode and the bank layer.

The black matrix may not overlap with the first electrode and the light-emitting layer.

Another embodiment of the present invention provides a display device including a display panel having pixels; and a cover substrate on the display panel, wherein the cover substrate includes a plurality of concave portions and a plurality of convex portions that are alternately disposed, and the cover substrate has an arithmetic mean roughness (Ra) of 0.25 μm or less and an average width (Rsm) of 10 μm or less.

The cover substrate may have a root mean square height (Sq) of 0.4 μm or less.

The cover substrate may have a maximum height (Sz) of 10.0 μm or less.

The cover substrate may have a root mean square variation (Sdq) in the range of 0.15 to 0.30.

The cover substrate may have an arithmetic mean peak curvature (Spc) in the range of 0.5 to 3.0.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a schematic diagram of a display device according to one embodiment of the present invention.

FIG. 2 is a schematic diagram of one embodiment of a display panel.

FIG. 3 is a plan view of the structure of the pixel illustrated in FIG. 2.

FIG. 4 is a cross-sectional view of the structure of a pixel according to one embodiment of the present invention.

FIG. 5 is a cross-sectional view of the structure of a pixel according to another embodiment of the present invention.

FIG. 6 is a cross-sectional view of the structure of a pixel according to another embodiment of the present invention.

FIG. 7 is a partial cross-sectional view of the anti-glare layer illustrated in FIG. 4.

FIG. 8 is a partial cross-sectional view of the cover substrate illustrated in FIG. 6.

FIG. 9 is a table showing the sparkling and haze of display devices according to examples and comparative examples of the present invention.

### DETAILED DESCRIPTION OF THE DISCLOSURE

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only~’ is used. The terms of a singular form may include plural forms unless referred to the contrary.

In construing an element, the element is construed as including an error band although there is no explicit description.

In describing a position relationship, for example, when the position relationship is described as ‘upon~’, ‘above~’, ‘below~’ and ‘next to~’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

Hereinafter, examples of the present invention will be described with reference to the attached drawings and examples. The scales of the components illustrated in the drawings are different from the actual scale for convenience of explanation, and are therefore not limited to the scales illustrated in the drawings.

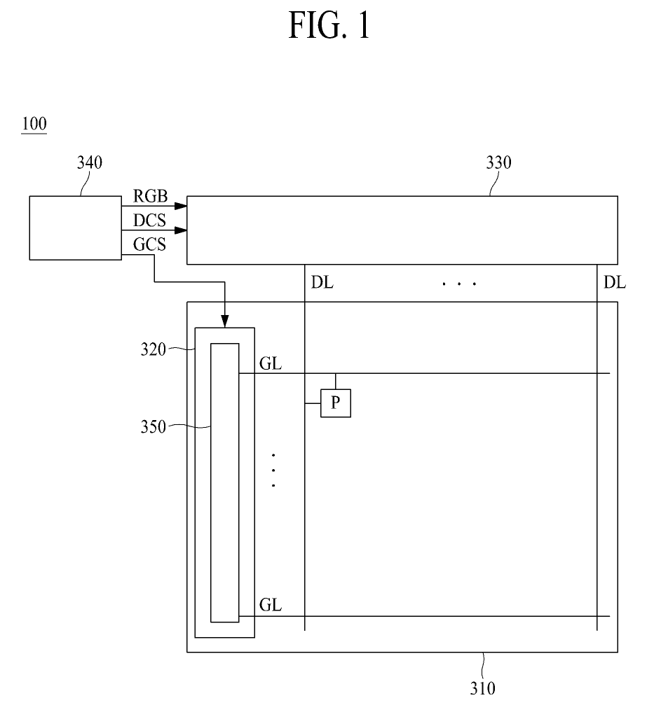

FIG. 1 is a schematic diagram of a display device (100) according to one embodiment of the present invention.

The display device (100) according to another embodiment of the present invention may include a display panel (310), a gate driver (320), a data driver (330), and a control unit (340), as illustrated in FIG. 1.

Gate lines (GL) and data lines (DL) are disposed on the display panel (310), and pixels (P) are disposed in the intersection area of the gate lines (GL) and data lines (DL). An image is displayed by driving the pixels (P).

The control unit (340) controls the gate driver (320) and the data driver (330).

The control unit (340) outputs a gate control signal (GCS) for controlling the gate driver (320) and a data control signal (DCS) for controlling the data driver (330) using a signal supplied from an external system (not shown). In addition, the control unit (340) samples input image data input from the external system, rearranges it, and supplies the redisposed digital image data (RGB) to the data driver (330).

The gate control signal (GCS) includes a gate start pulse (GSP), a gate shift clock (GSC), a gate output enable signal (GOE), a start signal (Vst), and a gate clock (GCLK). In addition, the gate control signal (GCS) may include control signals for controlling a shift register (350).

The data control signal (DCS) includes a source start pulse (SSP), a source shift clock signal (SSC), a source output enable signal (SOE), and a polarity control signal (POL).

The data driver (330) supplies data voltage to the data lines (DL) of the display panel (310). Specifically, the data driver (330) converts image data (RGB) input from the control unit (340) into analog data voltage and supplies the data voltage to the data lines (DL).

The gate driver (320) may include a shift register (350).

The shift register (350) sequentially supplies gate pulses to the gate lines (GL) for one frame using a start signal and a gate clock transmitted from the control unit (340). Here, one frame refers to a period during which one image is output through the display panel (310). The gate pulse has a turn-on voltage capable of turning on a switching element (thin film transistor) disposed in a pixel (P).

Additionally, the shift register (350) supplies a gate-off signal capable of turning off the switching element to the gate line (GL) during the remaining period during which the gate pulse is not supplied during one frame. Hereinafter, the gate pulse and the gate-off signal are collectively referred to as a scan signal (SS or Scan).

According to one embodiment of the present invention, the gate driver (320) may be mounted on the display panel (310). In this way, a structure in which the gate driver (320) is directly mounted on the display panel (310) is called a Gate In Panel (GIP) structure.

The gate driver (320) may include a plurality of thin film transistors. The plurality of thin film transistors may be disposed in a shift register (350).

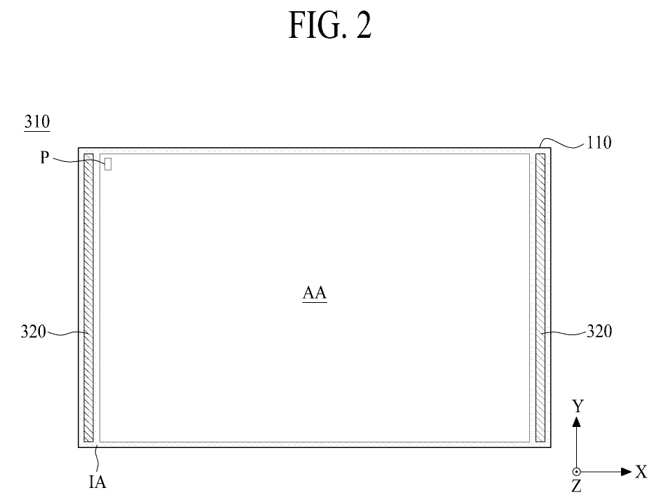

FIG. 2 is a schematic diagram of one embodiment of a display panel (310). FIG. 2 illustrates an organic light-emitting panel as an example of a display panel (310) applied to a display device (100). The display device (100) of FIG. 1 including an organic light-emitting panel can be an organic light-emitting display device.

Referring to FIG. 2, the display panel (310) includes a substrate (110) and pixels (P) on the substrate (110).

A glass substrate or a plastic substrate may be used as the substrate (110). The substrate (110) may include a display area (AA) and a non-display area (IA).

The display area (AA) is an area where an image is displayed, and may be referred to as a pixel array area, an active area, a pixel array unit, a display unit, or a screen. The display area (AA) includes a plurality of pixels (P).

A plurality of pixels (P) may be disposed along a first direction (X) and a second direction (Y) crossing the first direction (X). For example, the first direction (X) may be referred to as a first longitudinal direction, a long-side longitudinal direction, a horizontal direction, or a first horizontal direction of the substrate (110). In addition, the second direction (Y) may be referred to as a second longitudinal direction, a short-side longitudinal direction, a vertical direction, a second horizontal direction, or a vertical direction of the substrate (110).

Each of the plurality of pixels (P) may include a plurality of adjacent sub-pixels (SP). For example, a plurality of sub-pixels (SP) may constitute one pixel (P).

A non-display area (IA) is an area where an image is not displayed. The non-display area (IA) may include at least one of a peripheral circuit area, a signal supply area, an inactive area, and a bezel area. The non-display area (IA) may also be referred to as, for example, a peripheral circuit area, a signal supply area, an inactive area, or a bezel area.

The non-display area (IA) may be configured to surround the display area (AA). The display panel (310) may include a gate driver (320) disposed in the non-display area (IA) of the substrate (110). The gate driver (320) may also be referred to as a peripheral circuit. The gate driver (320) may be disposed on both sides of the substrate (110).

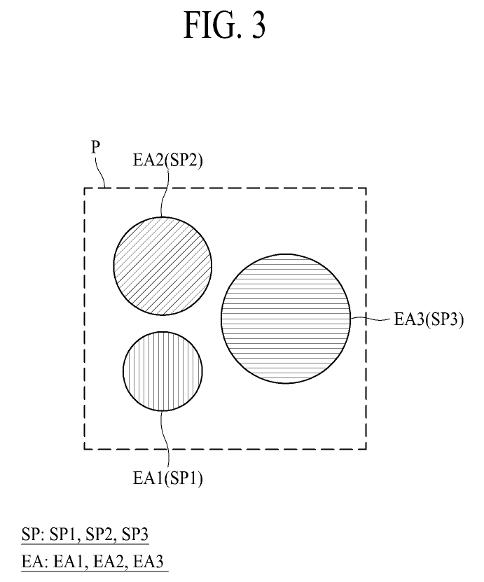

FIG. 3 is a plan view of the structure of the pixel (P) illustrated in FIG. 2. In FIGS. 2 and 3, the X-axis is the horizontal direction of the drawing, the Y-axis is the vertical direction of the drawing, and the Z-axis is the thickness direction.

Referring to FIGS. 2 and 3, in the display panel (310) of the display device (100) according to one embodiment of the present invention, each of the plurality of pixels (P) may include, for example, three sub-pixels (SP1, SP2, SP3).

In one embodiment of the present invention, a pixel (P) may include first, second, and third sub-pixels (SP1, SP2, SP3) that are spaced apart from each other. For example, each of the plurality of pixels (P) may include a first sub-pixel (SP1) that emits red light, a second sub-pixel (SP2) that emits green light, and a third sub-pixel (SP3) that emits blue light, but the present invention is not limited thereto. According to one embodiment of the present invention, each of the first to third sub-pixels (SP1 to SP3) may be configured to have different sizes or areas.

Each of the first to third sub-pixels (SP1 to SP3) may include a light-emitting portion (EA) and a circuit region. Specifically, the first sub-pixel (SP1) may include a first light-emitting portion (EA1), the second sub-pixel (SP2) may include a second light-emitting portion (EA2), and the third sub-pixel (SP3) may include a third light-emitting portion (EA3). The light-emitting portions (EA) described below may correspond to the first light-emitting portion (EA1), the second light-emitting portion (EA2), and the third light-emitting portion (EA3).

According to one embodiment of the present invention, the light-emitting portion (EA) may be referred to as an aperture region or a light-emitting region. The light-emitting portion (EA) may refer to a region excluding the bank layer (134) in a plan view. Specifically, the light-emitting portion (EA) may refer to a region in which the light-emitting layer (132) is disposed in a plan view.

According to one embodiment of the present invention, the first light emitting portion (EA1), the second light emitting portion (EA2), and the third light emitting portion (EA3) may be formed in a circle shape in a plan view.

In the related art, the light-emitting portion may have a polygonal shape in a plan view. For example, the light-emitting portion may have a triangular shape, a square shape, or the like. However, when the light-emitting portion has a polygonal shape, externally incident light may reach the edges of the light-emitting portion and be reflected therefrom.

According to one embodiment of the present invention, since the light emitting portion (EA) is formed in a circular shape in a plan view, even if light incident from the outside is reflected at the corner of the light emitting portion (EA), a phenomenon in which the reflected light is canceled out can occur. This is because the reflected light cancels out each other while the incident light reaches the circular corner and is reflected at various angles. That is, from the user's perspective, the light reflected in different directions cancels each other, so that the light reflected internally is not visible. As a result, the arrangement of the plurality of sub-pixels (SP) becomes uniform, and the resolution of the display device (100) can be increased.

Therefore, in order to prevent external light from being reflected inside the display panel (310), the light emitting portion (EA) needs to be formed in a circular shape on a flat surface.

According to one embodiment of the present invention, the first light emitting portion (EA1), the second light emitting portion (EA2), and the third light emitting portion (EA3) may have different diameters.

According to one embodiment of the present invention, the third light-emitting portion (EA3) of the third sub-pixel (SP3) may have the largest size, and the first light-emitting portion (EA1) of the first sub-pixel (SP1) may have the smallest size. The third light-emitting portion (EA3) of the third sub-pixel (SP3) may be larger than the second light-emitting portion (EA2) of the second sub-pixel (SP2), and the second light-emitting portion (EA2) of the second sub-pixel (SP2) may have a larger size than the first light-emitting portion (EA1) of the first sub-pixel (SP1). Specifically, the diameter of the third light-emitting portion (EA3) may be larger than the diameter of the second light-emitting portion (EA2), and the diameter of the second light-emitting portion (EA2) may be larger than the diameter of the first light-emitting portion (EA1).

The size of the light emitting portion (EA) can be determined in terms of lifetime and efficiency. More specifically, the size of the light emitting portion (EA) may be made smaller as the lifespan of the light emitting portion (EA) increases and the luminous efficiency increases. Conversely, the size of the light emitting portion (EA) may be made larger as the lifespan of the light emitting portion (EA) decreases and the luminous efficiency decreases.

For example, since the lifespan of the first light-emitting portion (EA1) of the first sub-pixel (SP1) that emits red light is longer than the lifespan of the second light-emitting portion (EA2) of the second sub-pixel (SP2) that emits green light and the lifespan of the third light-emitting portion (EA3) of the third sub-pixel (SP3) that emits blue light, the size of the first light-emitting portion (EA1) can be formed to be the smallest in order to match the lifespan ratios of the first light-emitting portion (EA1), the second light-emitting portion (EA2), and the third light-emitting portion (EA3). Conversely, since the lifespan of the third light-emitting portion (EA3) of the third sub-pixel (SP3) that emits blue light is shorter than the lifespan of the first light-emitting portion (EA1) of the first sub-pixel (SP1) that emits red light and the lifespan of the second light-emitting portion (EA2) of the second sub-pixel (SP2) that emits green light, the size of the third light-emitting portion (EA3) can be formed as large as possible to match the lifespan ratios of the first light-emitting portion (EA1), the second light-emitting portion (EA2), and the third light-emitting portion (EA3).

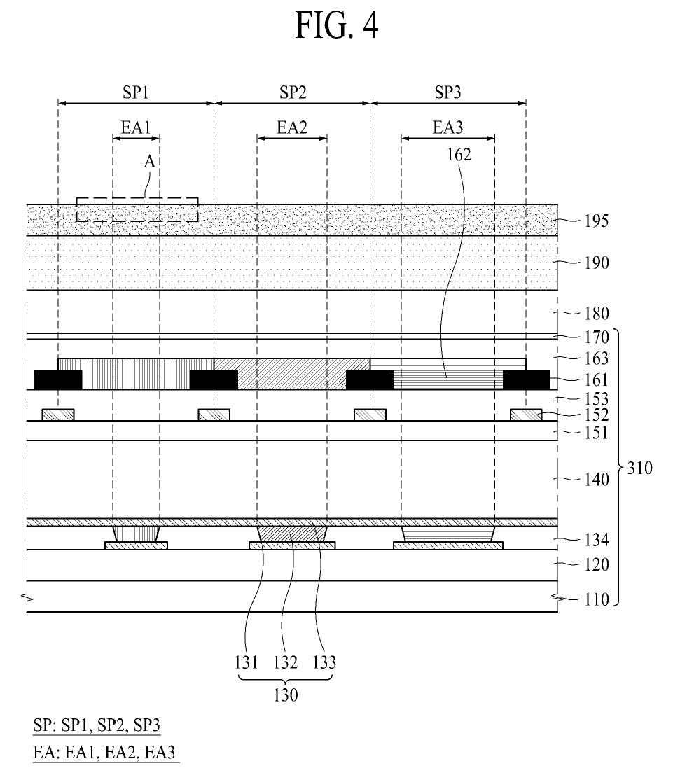

FIG. 4 is a cross-sectional view of the structure of a pixel (P) according to one embodiment of the present invention. Specifically, FIG. 4 is a cross-sectional view of the structure of the pixel (P) illustrated in FIG. 3.

Referring to FIGS. 3 and 4, a display device (100) according to an embodiment of the present invention includes a display panel (310) including pixels (P), a cover substrate (190) on the display panel (310), and an anti-glare layer (195) on the cover substrate (190). The display panel (310) may include a substrate (110), a pixel circuit layer (120), an organic light-emitting element (130), an encapsulation portion (140), a first touch buffer layer (151), a touch electrode (152), a second touch buffer layer (153), a black matrix (161), color filters (162), an overcoating layer (163), and an inorganic film (170).

The substrate (110) may also be referred to as a first substrate, a base substrate, a lower substrate, a glass substrate, a plastic substrate, or a base member. According to one embodiment of the present invention, glass or plastic may be used as the substrate (110). A transparent plastic having flexible properties, such as polyimide, may be used as the plastic. When polyimide is used as the substrate (110), considering that a high-temperature deposition process is performed on the substrate (110), a heat-resistant polyimide that can withstand high temperatures may be used.

A pixel circuit layer (120) may be disposed on a substrate (110). The pixel circuit layer (120) may include a buffer layer and a pixel circuit.

The buffer layer may be disposed on the first surface or the entire upper surface of the substrate (110). The buffer layer may serve to block materials contained in the substrate (110) from diffusing into the transistor layer during a high-temperature process during the manufacturing process of the thin film transistor, or may serve to prevent external moisture or humidity from penetrating toward the organic light-emitting element (130). Optionally, the buffer layer may be omitted.

The pixel circuit may include a driving thin film transistor disposed in a circuit area of each sub-pixel (SP). The driving thin film transistor may include an active layer, a gate insulating film, a gate electrode, an interlayer insulating film, a drain electrode, and a source electrode.

The pixel circuit may further include at least one capacitor and at least one switching thin film transistor disposed in a circuit area together with the driving thin film transistor.

The display device (100) according to one embodiment of the present invention may further include a light-blocking layer. The light-blocking layer may be disposed on the substrate (110) to overlap with the active layer, and configured to minimize or prevent a change in the threshold voltage of the thin film transistor due to external light. According to the present specification, the light-blocking layer may be disposed under the active layer of the driving thin film transistor or the switching thin film transistor.

The organic light-emitting element (130) may be disposed in the light-emitting portion (EA) of each sub-pixel (SP). According to one embodiment of the present invention, the organic light-emitting element (130) may include a first electrode (131), a light-emitting layer (132), and a second electrode (133).

According to one embodiment of the present invention, the first electrode (131), the light-emitting layer (132), and the second electrode (133) may be configured to emit light toward the opposite side of the substrate (110) according to a top emission method, or may be configured to emit light toward the substrate (110) according to a bottom emission method.

Hereinafter, embodiments of the present invention will be described, focusing on a display device (100) including an organic light-emitting element (130) configured to emit light toward the opposite side of a substrate (110) according to a top emission method.

The first electrode (131) can be disposed on the pixel circuit layer (120) and electrically connected to the source electrode of the driving thin film transistor.

The light-emitting layer (132) is formed on the first electrode (131) and can be in direct contact with the first electrode (131).

The second electrode (133) is disposed on the light-emitting layer (132) and can be in direct contact with the light-emitting layer (132). The second electrode (133) can have a relatively thin thickness compared to the light-emitting layer (132).

According to one embodiment of the present invention, for top emission, the first electrode (131) may have a structure capable of reflecting light emitted and incident from the light-emitting layer (132) toward the opposite side of the substrate (110). In order to reflect light emitted and incident from the light-emitting layer (132) toward the opposite side of the substrate (110), the first electrode (131) may include a metal material having high reflectivity. For example, the first electrode (131) may have a single-layer structure or a multi-layer structure made of one material selected from aluminum (Al), silver (Ag), molybdenum (Mo), gold (Au), magnesium (Mg), calcium (Ca), or barium (Ba), or an alloy material of two or more materials. The first electrode (131) may be an anode electrode.

The second electrode (133) may have light transparency. According to one embodiment of the present invention, the second electrode (133) may have both light transparency and light reflection. The second electrode (133) may have a multilayer structure including, for example, a layer made of a transparent conductive oxide (TCO) and a layer made of a metal with a low work function. The second electrode (133) may be a cathode electrode.

The display device (100) according to one embodiment of the present invention may further include a bank layer (134). The bank layer (134) may overlap an edge of the first electrode (131) and be disposed on the pixel circuit layer (120). The bank layer (134) may be made of a transparent material or an opaque material. For example, the bank layer (134) may be a transparent bank layer or a black bank layer. For example, the bank layer (134) may include a black pigment, in which case the bank layer (134) may also function as a light-blocking member between adjacent sub-pixels (SP).

The encapsulation portion (140) may be formed on the substrate (110) to surround or cover the organic light-emitting element (130). The encapsulation portion (140) may be disposed on the second electrode (133). For example, the encapsulation portion (140) may surround the display area (AA). The encapsulation portion (140) may protect the thin film transistor and the light-emitting layer (132) from external impact, and may serve to prevent oxygen, moisture, or foreign particles from penetrating into the light-emitting layer (132).

According to one embodiment of the present invention, the encapsulating portion (140) may include a plurality of inorganic encapsulating layers. The encapsulating portion (140) may further include at least one organic encapsulating layer interposed between the plurality of inorganic encapsulating layers.

According to one embodiment of the present invention, a first touch buffer layer (151) may be disposed on the encapsulation portion (140). The first touch buffer layer (151) may be composed of an inorganic insulating film, and may be an insulating film containing silicon, such as SiNx, SiOx, or SiON, but is not limited thereto.

According to one embodiment of the present invention, the touch electrode (152) may be disposed on the first touch buffer layer (151). Specifically, the touch electrode (152) may be disposed as a touch sensor for touch sensing.

The touch electrode (152) can be formed as a metal layer, and can be formed as a single layer or multiple layers of conductive metals such as copper (Cu), aluminum (Al), molybdenum (Mo), chromium (Cr), gold (Au), titanium (Ti), nickel (Ni), and neodymium (Nd), or alloys thereof, but is not limited thereto.

According to one embodiment of the present invention, a second touch buffer layer (153) may be disposed on the touch electrode (152). The second touch buffer layer (153) may be composed of an inorganic insulating film, and may be an insulating film containing silicon, such as SiNx, SiOx, or SiON, but is not limited thereto.

A display device (100) according to one embodiment of the present invention may further include color filters (162). The color filters (162) may be disposed in a direction in which light is emitted from the organic light-emitting element (130). According to an embodiment of the present invention, the color filters (162) may be disposed on an opposite side of the substrate (110) with respect to the organic light-emitting element (130).

The color filters (162) may be disposed on the organic light-emitting element (130) so as to overlap with at least one light-emitting portion (EA). According to one embodiment of the present invention, the color filters (162) may be disposed on the encapsulation portion (140).

The color filters (162) may have a larger size than the light-emitting portion (EA). For example, the edge portions of the color filters (162) may overlap with the bank layer (134). According to one embodiment of the present invention, the color filters (162) may have a size corresponding to each sub-pixel (SP), thereby reducing light leakage between adjacent sub-pixels (SP).

According to one embodiment of the present invention, the color filters (162) may be configured to transmit the wavelength of the color set in the sub-pixel (SP). For example, as illustrated in FIG. 3, when one pixel (P) includes first, second, and third sub-pixels (SP1, SP2, SP3), the color filters (162) may include a red color filter provided in the first sub-pixel (SP1), a green color filter provided in the second sub-pixel (SP2), and a blue color filter provided in the third sub-pixel (SP3).

According to one embodiment of the present invention, the color filters (162) can be formed on the encapsulation portion (140) so as to overlap with the light-emitting portion (EA).

A display device (100) according to one embodiment of the present invention may further include a black matrix (161) disposed between color filters (162).

The black matrix (161) can be disposed to overlap with the remaining area except for the light-emitting portion (EA) of each sub-pixel (SP).

According to one embodiment of the present invention, the black matrix (161) and the touch electrode (152) may overlap each other. Specifically, since the black matrix (161) is disposed in the area where the touch electrode (152) is disposed, external light can be more effectively prevented or suppressed from being reflected by the touch electrode (152). As a result, the visibility due to reflection by external light may be reduced.

According to one embodiment of the present invention, the black matrix (161), the touch electrode (152), and the bank layer (134) may overlap each other. Specifically, the black matrix (161) may overlap at least a portion of the bank layer (134). In addition, the touch electrode (152) may overlap at least a portion of the bank layer (134).

According to one embodiment of the present invention, the black matrix (161) may not overlap with the first electrode (131) and the light-emitting layer (132). For example, in cross-section, the black matrix (161) may be disposed to be spaced apart from the first electrode (131) and the light-emitting layer (132).

Referring to FIG. 4, an overcoating layer (163) may be disposed on the color filters (162). The overcoating layer (163) may protect the color filters (162) and flatten the upper portions of the color filters (162). The overcoating layer (163) may also be referred to as a protective layer. The overcoating layer (163) may also be omitted.

According to one embodiment of the present invention, an inorganic film (170) may be disposed on an overcoating layer (163). The inorganic film (170) may be formed as a multi-film in which one or more inorganic layers of a silicon oxide film (SiOx), a silicon nitride film (SiNx), and SiON are alternately laminated.

According to one embodiment of the present invention, an adhesive member (180) may be disposed on an inorganic film (170). The adhesive member (180) may be disposed between the inorganic film (170) and the cover substrate (190) so that the inorganic film (170) may be bonded to the cover substrate (190).

Referring to FIG. 4, the laminate from the substrate (110) to the inorganic film (170) may be referred to as a display panel (310).

A display device (100) according to one embodiment of the present invention includes a cover substrate (190) disposed on a display panel (310). An adhesive member (180) may be disposed between the display panel (310) and the cover substrate (190). The cover substrate (190) may be attached and fixed to the display panel (310) by the adhesive member (180).

As the cover substrate (190), a glass substrate or a transparent plastic substrate may be used. Light generated from the organic light-emitting element (160) of the display panel (310) may be emitted to the outside through the cover substrate (190). In addition, external light (external light) may be incident through the cover substrate (190), and the external light may be reflected by the cover substrate (190).

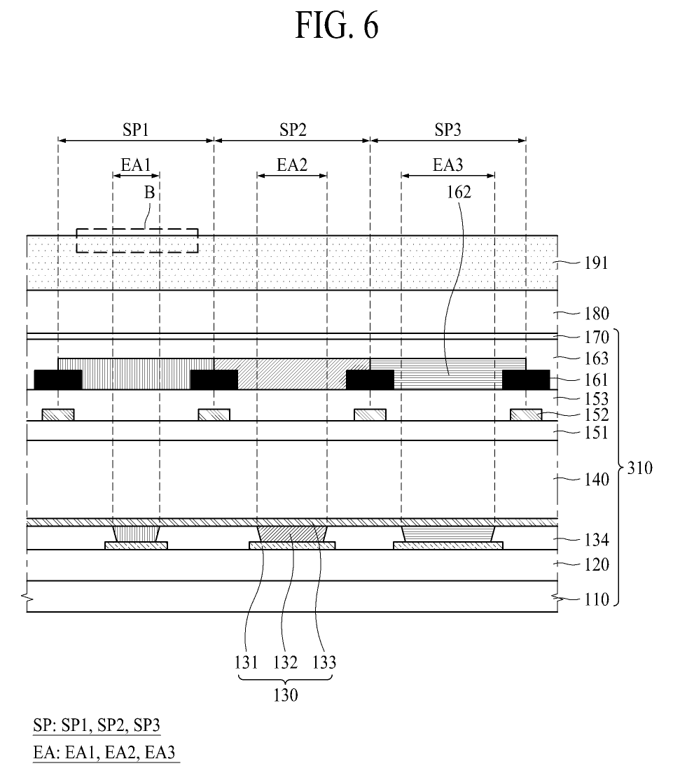

When external light is reflected from the cover substrate (190), glare occurs on the cover substrate (190), and the image reflected on the cover substrate (190) may be visible to the user. To prevent such glare and the reflection image, the cover substrate (191) may be matte-treated (see FIGS. 6 and 8). Referring to FIGS. 6 and 8, the matte treatment for the cover substrate (191) may include, for example, forming a micro-patterns on the cover substrate (191).

The micro-pattern formed on the cover substrate (191) is a random pattern. However, a sparkling phenomenon may occur due to the irregularity or non-uniformity of the multiple randomly disposed patterns (or random patterns).

According to one embodiment of the present invention, an anti-glare layer (195) can be formed on the cover substrate (190) without applying a matte treatment to the cover substrate (190) (see FIGS. 4, 5, and 7). The anti-glare layer (195) can cover the entire upper surface of the cover substrate (190).

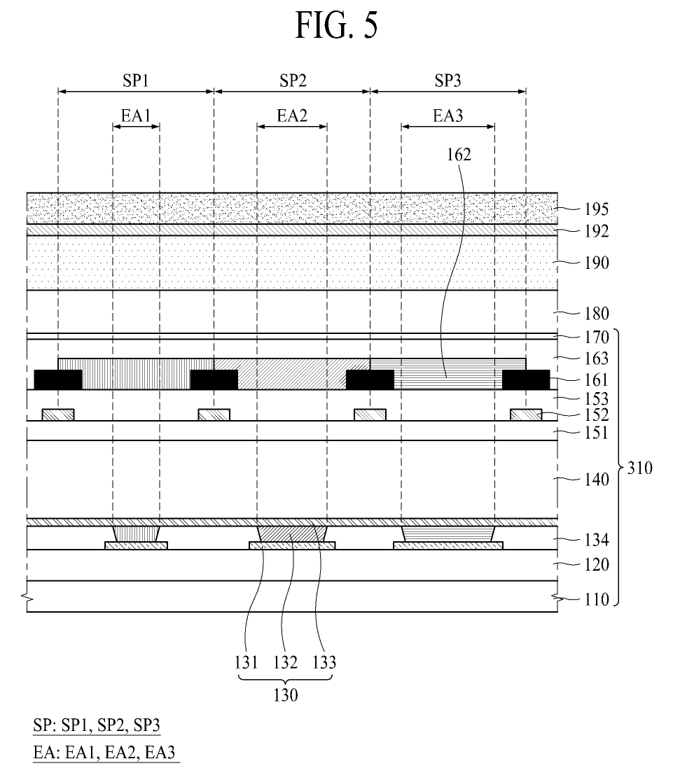

Referring to FIG. 5, a resin layer (192) may be disposed between a cover substrate (190) and an anti-glare layer (195). According to one embodiment of the present invention, the cover substrate (190) and the anti-glare layer (195) may be bonded by the resin layer (192). The resin layer (192) may be an optically clear resin layer (OCR).

Referring to FIG. 4, the cover substrate (190) and the anti-glare layer (195) can be in contact.

According to one embodiment of the present invention, in order to prevent the phenomenon of glare and reflection image recognition, the anti-glare layer (195) may be matte-treated (see FIGS. 4, 5, and 7).

The anti-glare layer (195) illustrated in FIGS. 4, 5, and 7 and the cover substrate (191) illustrated in FIGS. 6 and 8 are described in detail below.

The sparkling phenomenon may refer to a phenomenon in which internal light is scattered by irregular micro-patterns, thereby generating irregular sparkling. This sparkling phenomenon is particularly noticeable in a display device (100) including a self-luminous light-emitting element. For example, in a display panel (310) including an organic light-emitting element (130), which is a self-luminous display element, when light generated from the organic light-emitting element (130) is emitted to the outside through the display panel (310) and the cover substrate (190), the sparkling phenomenon may refer to a phenomenon in which internal light is scattered in response to the spacing between a plurality of randomly disposed patterns, thereby generating irregular sparkling.

As described above, since the first light emitting portion (EA1), the second light emitting portion (EA2), and the third light emitting portion (EA3) are formed in a circular shape, as the resolution of the display device (100) increases, many pixels (P) are densely packed in a small area. As a result, the number of pixels (P) that interfere with the micro-pattern increases, which increases the sparkling phenomenon due to the micro-pattern, resulting in a problem of reduced visibility.

Therefore, the display device (100) according to one embodiment of the present invention needs to secure a sparkling value of 5% or less to increase visibility.

Additionally, in order to secure outdoor visibility or an anti-glare effect for the display panel (310), an appropriate haze value needs to be secured.

The haze phenomenon may refer to a phenomenon in which a display surface of the display device (100) appears cloudy. In addition, the haze phenomenon may be caused by irregular micro-patterns that scatter light, thereby having an effect of suppressing specular reflection in which external light sources or external objects are mirror-reflected inside the display panel (310). In this case, the display surface may refer to a surface viewed from the outside toward the cover substrate (190).

If the haze value is not sufficiently secured, diffuse reflection caused by the irregular micro-patterns may not be properly controlled, and thus sufficient visibility may not be ensured. For example, when the haze value is insufficient and is less than 20%, visibility may be degraded due to a phenomenon in which external objects are reflected on the display surface. Therefore, the display device (100) according to an embodiment of the present invention is intended to secure a haze value of 20% or more in order to reduce interference from externally reflected light and to improve visibility.

However, in the related art, a problem has occurred in that the sparkling value increases in the process of adjusting micro-patterns to increase the haze value of the display device (100). Specifically, when the roughness of the micro-patterns is increased to increase the haze value, internal light may be excessively scattered by the irregular micro-patterns, thereby causing the sparkling phenomenon to become more noticeable.

According to one embodiment of the present invention, the roughness of the anti-glare layer (195) illustrated in FIGS. 4, 5, and 7 and the cover substrate (191) illustrated in FIGS. 6 and 8 can be adjusted to maintain the haze value of the display device (100) at 20% or more while maintaining the sparkling value at 5% or less. First, the roughness of the anti-glare layer (195) illustrated in FIGS. 4, 5, and 7 will be described.

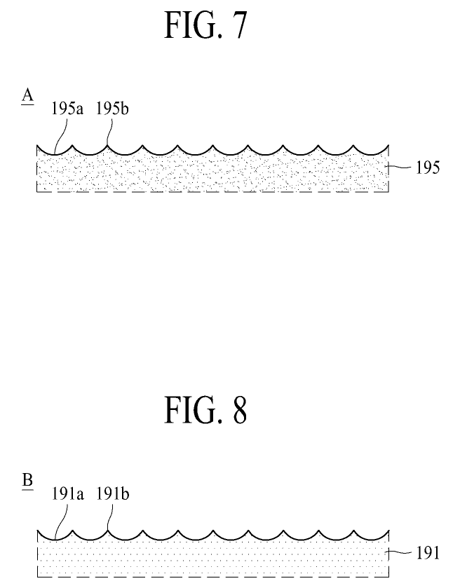

FIG. 4 is a cross-sectional view of the structure of a pixel (P) according to one embodiment of the present invention. FIG. 5 is a cross-sectional view of the structure of a pixel (P) according to another embodiment of the present invention. FIG. 7 is a partial cross-sectional view of the anti-glare layer (195) illustrated in FIG. 4. FIG. 7 may be a partial cross-sectional view of the anti-glare layer (195) illustrated in FIG. 5.

Referring to FIG. 7, the anti-glare layer (195) may include a plurality of concave portions (195a) and a plurality of convex portions (195b) that are alternately disposed. The concave portions (195a) may be disposed between the plurality of convex portions (195b), and the convex portions (195b) may be disposed between the plurality of concave portions (195a). The thickness of the anti-glare layer (195) may be thicker in an area corresponding to the convex portions (195b) than in an area corresponding to the concave portions (195a).

According to one embodiment of the present invention, a plurality of concave portions (195a) and a plurality of convex portions (195b) may correspond to the irregular micro-pattern described above.

According to one embodiment of the present invention, the anti-glare layer (195) may have an arithmetic mean roughness (Ra) of 0.25 μm or less. The arithmetic mean roughness (Ra) according to one embodiment of the present invention may be measured using a surface roughness measuring device (Zygo) according to ISO 4287. The arithmetic mean roughness (Ra) may mean the average of the absolute values of the height deviation of the surface profile based on the center line (mean line) of the measured surface.

When the anti-glare layer (195) has an arithmetic mean roughness (Ra) of 0.25 μm or less, the haze value of the display device (100) can be maintained at 20% or more while the sparkling value can be maintained at 5% or less.

On the other hand, if the arithmetic mean roughness (Ra) of the anti-glare layer (195) exceeds 0.25 μm, the sparkling value of the display device may exceed 5%.

However, even when the anti-glare layer (195) satisfies an arithmetic average roughness (Ra) of 0.25 μm or less, if the anti-glare layer (195) does not satisfy an average width (Rsm) of 10 μm or less, it is not possible to maintain a haze value of 20% or more while keeping a sparkling value of 5% or less in the display device (100).

According to one embodiment of the present invention, the anti-glare layer (195) may have an average width (Rsm) of 10 μm or less. The average width (Rsm) may be defined as an average value for the distances of profile elements within a sampling length. For example, the average width (Rsm) may be defined as an average value for the distances between peaks of each of a plurality of convex portions (195b). In this case, the peak may mean the uppermost portion of the convex portion (195b). According to one embodiment of the present invention, the average width (Rsm) may be measured using a surface roughness measuring device (Zygo) according to the ISO 4287 standard.

When the anti-glare layer (195) has an average width (Rsm) of 10 μm or less, the haze value of the display device (100) can be maintained at 20% or more while the sparkling value can be maintained at 5% or less.

On the other hand, when the average width (Rsm) of the anti-glare layer (195) exceeds 10 μm, the sparkling value of the display device may exceed 5% and the haze value may be less than 20%.

However, even when the anti-glare layer (195) satisfies an average width (Rsm) of 10 μm or less, if the anti-glare layer (195) does not satisfy an arithmetic average roughness (Ra) of 0.25 μm or less, it is not possible to maintain a haze value of 20% or more while keeping a sparkling value of 5% or less in the display device (100).

Therefore, in order to maintain the haze value of the display device (100) according to the present invention at 20% or more and the sparkling value at 5% or less, the anti-glare layer (195) needs to have an arithmetic mean roughness (Ra) of 0.25 μm or less and an average width (Rsm) of 10 μm or less.

According to one embodiment of the present invention, the anti-glare layer (195) may have a root mean square height (Sq) of 0.4 μm or less. According to one embodiment of the present invention, the root mean square height (Sq) may be measured using a surface roughness meter (Zygo) according to ISO 25178. The root mean square height (Sq) is a parameter corresponding to the standard deviation of the distance from the mean plane. The closer the root mean square height (Sq) is to 0, the flatter the surface is. Preferably, the root mean square height (Sq) may be 0.3 μm or less.

When the anti-glare layer (195) has a root mean square height (Sq) of 0.4 μm or less, the haze value of the display device (100) can be maintained at 20% or more while the sparkling value can be maintained at 5% or less.

On the other hand, when the root mean square height (Sq) of the anti-glare layer (195) exceeds 0.4 μm, the sparkling value of the display device may exceed 5% or the haze value may be less than 20%.

According to one embodiment of the present invention, the anti-glare layer (195) may have a maximum height (Sz) of 10.0 μm or less. According to one embodiment of the present invention, the maximum height (Sz) may be measured with a surface roughness meter (Zygo) according to the ISO 25178 standard. According to the present invention, the maximum height (Sz) is a value obtained by adding the maximum peak height (Sp) and the maximum valley height (Sv) in a graph showing peaks. At this time, the maximum peak height (Sp) may correspond to the maximum height of the convex portion (195b), and the maximum valley height (Sv) may correspond to the maximum depth of the concave portion (195a). Preferably, the maximum height (Sz) may be 8.0 μm or less.

When the anti-glare layer (195) has a maximum height (Sz) of 10.0 μm or less, the haze value of the display device (100) can be maintained at 20% or more while the sparkling value can be maintained at 5% or less.

On the other hand, when the maximum height (Sz) of the anti-glare layer (195) exceeds 10.0 μm, the sparkling value of the display device may exceed 5% or the haze value may be less than 20%.

According to one embodiment of the present invention, the anti-glare layer (195) may have a root mean square gradient (Sdq) in the range of 0.15 to 0.30. According to one embodiment of the present invention, the root mean square gradient (Sdq) may be measured using a surface roughness meter (Zygo) according to ISO 4287. According to the present invention, the root mean square gradient (Sdq) is a variable representing the steepness of the unevenness of the surface. For example, when the unevenness is completely flat, the root mean square gradient (Sdq) may be 0.

When the anti-glare layer (195) has a root mean square gradient (Sdq) in the range of 0.15 to 0.30, the haze value of the display device (100) can be maintained at 20% or more while the sparkling value can be maintained at 5% or less.

On the other hand, if the root mean square variation (Sdq) of the anti-glare layer (195) is outside the range of 0.15 to 0.30, the sparkling value of the display device may exceed 5% or the haze value may be less than 20%.

According to one embodiment of the present invention, the anti-glare layer (195) may have an arithmetic mean peak curvature (Spc) in the range of 0.5 to 3.0. According to one embodiment of the present invention, the arithmetic mean peak curvature (Spc) may be measured using a surface roughness meter (Keyence Co.) according to ISO 25178. According to the present invention, the arithmetic mean peak curvature (Spc) may mean the arithmetic mean of the principal curvatures of the surface peaks. For example, the smaller the value of the arithmetic mean peak curvature (Spc), the rounder the peak, and the larger the value, the sharper the peak.

When the anti-glare layer (195) has an arithmetic mean peak curvature (Spc) in the range of 0.5 to 3.0, the haze value of the display device (100) can be maintained at 20% or more while the sparkling value can be maintained at 5% or less.

On the other hand, if the arithmetic mean peak curvature (Spc) of the anti-glare layer (195) is outside the range of 0.5 to 3.0, the sparkling value of the display device may exceed 5% or the haze value may be less than 20%.

FIG. 6 is a cross-sectional view of the structure of a pixel (P) according to another embodiment of the present invention. FIG. 8 is a partial cross-sectional view of the cover substrate (191) illustrated in FIG. 6.

Referring to FIG. 8, the cover substrate (191) may include a plurality of concave portions (191a) and a plurality of convex portions (191b) that are alternately disposed. The concave portions (191a) may be disposed between the plurality of convex portions (191b), and the convex portions (191b) may be disposed between the plurality of concave portions (191a). The thickness of the cover substrate (191) may be thicker in an area corresponding to the convex portions (191b) than in an area corresponding to the concave portions (191a).

According to one embodiment of the present invention, a plurality of concave portions (191a) and a plurality of convex portions (191b) may correspond to the irregular micro-pattern described above.

According to one embodiment of the present invention, the cover substrate (191) may have an arithmetic mean roughness (Ra) of 0.25 μm or less.

When the cover substrate (191) has an arithmetic mean roughness (Ra) of 0.25 μm or less, the haze value of the display device (100) can be maintained at 20% or more while the sparkling value can be maintained at 5% or less.

On the other hand, when the arithmetic mean roughness (Ra) of the cover substrate (191) exceeds 0.25 μm, the sparkling value of the display device may exceed 5%.

According to one embodiment of the present invention, the cover substrate (191) may have an average width (Rsm) of 10 μm or less.

When the cover substrate (191) has an average width (Rsm) of 10 μm or less, the haze value of the display device (100) can be maintained at 20% or more while the sparkling value can be maintained at 5% or less.

On the other hand, when the average width (Rsm) of the cover substrate (191) exceeds 10 μm, the sparkling value of the display device may exceed 5% and the haze value may be less than 20%.

Therefore, in order to maintain the haze value of the display device (100) according to the present invention at 20% or more and the sparkling value at 5% or less, the cover substrate (191) needs to have an arithmetic mean roughness (Ra) of 0.25 μm or less and an average width (Rsm) of 10 μm or less.

According to one embodiment of the present invention, the cover substrate (191) may have a root mean square height (Sq) of 0.4 μm or less.

When the cover substrate (191) has a root mean square height (Sq) of 0.4 μm or less, the haze value of the display device (100) can be maintained at 20% or more while the sparkling value can be maintained at 5% or less.

On the other hand, when the root mean square height (Sq) of the cover substrate (191) exceeds 0.4 μm, the sparkling value of the display device may exceed 5% or the haze value may be less than 20%.

According to one embodiment of the present invention, the cover substrate (191) may have a maximum height (Sz) of 10.0 μm or less.

When the cover substrate (191) has a maximum height (Sz) of 10.0 μm or less, the haze value of the display device (100) can be maintained at 20% or more while the sparkling value can be maintained at 5% or less.

On the other hand, when the maximum height (Sz) of the cover substrate (191) exceeds 10.0 μm, the sparkling value of the display device may exceed 5% or the haze value may be less than 20%.

According to one embodiment of the present invention, the cover substrate (191) may have a root mean square variation (Sdq) in the range of 0.15 to 0.30.

When the cover substrate (191) has a root mean square variation (Sdq) in the range of 0.15 to 0.30, the haze value of the display device (100) can be maintained at 20% or more while the sparkling value can be maintained at 5% or less.

On the other hand, when the root mean square variation (Sdq) of the cover substrate (191) is outside the range of 0.15 to 0.30, the sparkling value of the display device may exceed 5% or the haze value may be less than 20%.

According to one embodiment of the present invention, the cover substrate (191) may have an arithmetic mean peak curvature (Spc) in the range of 0.5 to 3.0.

When the cover substrate (191) has an arithmetic mean peak curvature (Spc) in the range of 0.5 to 3.0, the haze value of the display device (100) can be maintained at 20% or more while the sparkling value can be maintained at 5% or less.

On the other hand, when the arithmetic mean peak curvature (Spc) of the cover substrate (191) is outside the range of 0.5 to 3.0, the sparkling value of the display device may exceed 5% or the haze value may be less than 20%.

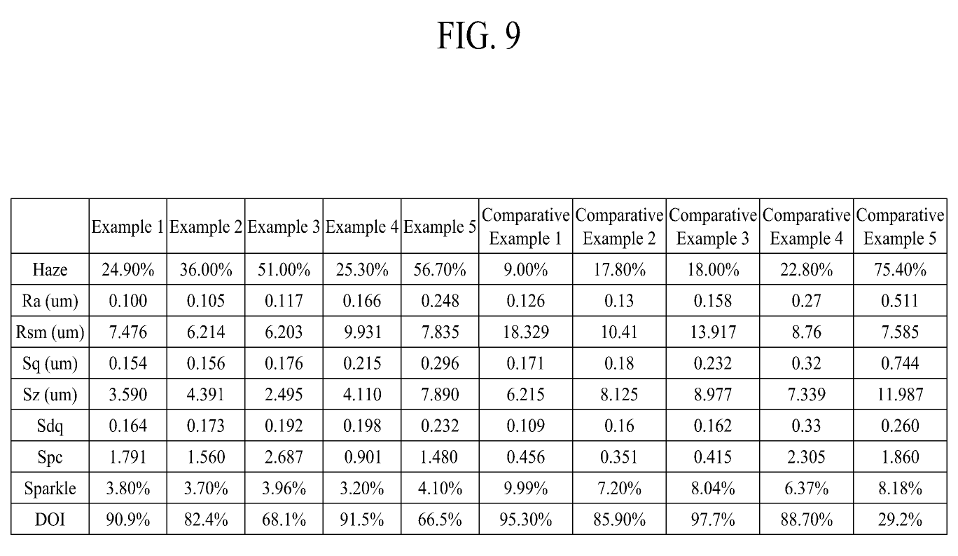

FIG. 9 is a table showing the sparkling and haze of display devices according to examples and comparative examples of the present invention. Specifically, Examples 1 to 5 of FIG. 9 are the display devices (100) of FIG. 4. In addition, the roughness of the anti-glare layer (195) of the display devices (100) of Examples 1 to 5 is as shown in the table. The roughness of the anti-glare layer of the display devices according to Comparative Examples 1 to 5 is as shown in the table.

Referring to FIG. 9, the display devices of Examples 1 to 5 can have a sparkling value of 5% or less while maintaining a haze value of 20% or more by satisfying an arithmetic mean roughness (Ra) of 0.25 μm or less and an average width (Rsm) of 10 μm or less.

Referring to FIG. 9, the display device of Comparative Example 1 has an arithmetic mean roughness (Ra) value of 0.25 μm or less, but an average width (Rsm) of more than 10 μm, so a problem may occur in which the sparkling value exceeds 5% and the haze value is less than 20%.

Referring to FIG. 9, the display device of Comparative Example 2 has an arithmetic mean roughness (Ra) value of 0.25 μm or less, but an average width (Rsm) of more than 10 μm, so a problem may occur in which the sparkling value exceeds 5% and the haze value is less than 20%.

Referring to FIG. 9, the display device of Comparative Example 3 has an arithmetic mean roughness (Ra) value of 0.25 μm or less, but an average width (Rsm) of more than 10 μm, so a problem may occur in which the sparkling value exceeds 5% and the haze value is less than 20%.

Referring to FIG. 9, the display device of the comparison 4 has an average width (Rsm) of 10 μm or less, but an arithmetic mean roughness (Ra) value exceeding 0.25 μm, which may cause a problem in which the sparkling value exceeds 5%.

Referring to FIG. 9, the display device of Comparative Example 5 has an average width (Rsm) of 10 μm or less, but an arithmetic mean roughness (Ra) value exceeding 0.25 μm, which may cause a problem in which the sparkling value exceeds 5%.

Referring to FIG. 9, DOI (Distance of Image) may refer to the contrast ratio between a reference image and a sample image. Specifically, DOI can be said to be a factor indicating the clarity of a display device. According to the present invention, the display device must have a DOI of 24% or more.

According to the present disclosure, the following advantageous effects may be obtained.

A display device according to one embodiment of the present invention can effectively reduce or prevent the occurrence of a sparkling phenomenon by including an anti-glare layer.

A display device according to one embodiment of the present invention can effectively reduce or prevent the occurrence of a sparkling phenomenon while having a high haze value by including an anti-glare layer.

In addition to the effects mentioned above, other features and advantages of the present invention are described below or may be clearly understood by those skilled in the art to which the present invention pertains from such description and explanation.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device comprising:
a display panel having pixels;
a cover substrate on the display panel; and
an anti-glare layer on the cover substrate,
wherein the anti-glare layer includes a plurality of concave portions and a plurality of convex portions that are alternately disposed, and
wherein the anti-glare layer has an arithmetic mean roughness (Ra) of 0.25 μm or less and an average width (Rsm) of 10 μm or less.

2. The display device of claim 1,
wherein a pixel of the pixels includes a plurality of sub-pixels having different light-emitting portions, and
wherein, in a plan view, the light-emitting portions of the plurality of sub-pixels are each formed in a circular shape.

3. The display device of claim 2,
wherein the plurality of sub-pixels includes a first sub-pixel configured to emit red light, a second sub-pixel configured to emit green light, and a third sub-pixel configured to emit blue light,
wherein the first sub-pixel includes a first light-emitting portion,
wherein the second sub-pixel includes a second light-emitting portion,
wherein the third sub-pixel includes a third light-emitting portion, and
wherein diameters of the first to third light-emitting portions are different from each other.

4. The display device of claim 3,
wherein a diameter of the third light-emitting portion is larger than a diameter of the second light-emitting portion, and
wherein the diameter of the second light-emitting portion is larger than a diameter of the first light-emitting portion.

5. The display device of claim 1,
wherein the anti-glare layer has a root mean square height (Sq) of 0.4 μm or less.

6. The display device of claim 1,
wherein the anti-glare layer has a maximum height (Sz) of 10.0 μm or less.

7. The display device of claim 1,
wherein the anti-glare layer has a root mean square gradient (Sdq) in a range of 0.15 to 0.30.

8. The display device of claim 1,
wherein the anti-glare layer has an arithmetic mean peak curvature (Spc) in a range of 0.5 to 3.0.

9. The display device of claim 1,
wherein the anti-glare layer covers an entire upper surface of the cover substrate.

10. The display device of claim 1, further comprising:
a resin layer disposed between the anti-glare layer and the cover substrate.

11. The display device of claim 1,
wherein the display panel comprises:
an organic light-emitting element disposed on a substrate;
an encapsulation portion disposed on the organic light-emitting element;
a touch electrode disposed on the encapsulation portion;
color filters disposed on the touch electrode; and
a black matrix disposed on the touch electrode and between the color filters.

12. The display device of claim 11,
wherein the organic light-emitting element comprises:
a first electrode;
a light-emitting layer disposed on the first electrode; and
a second electrode disposed on the light-emitting layer,
wherein the display panel further comprises a bank layer disposed on the substrate and overlapping an edge of the first electrode, and
wherein the black matrix overlaps the touch electrode and the bank layer.

13. The display device of claim 12,
wherein the black matrix does not overlap the first electrode and the light-emitting layer.

14. A display device comprising:
a display panel having pixels; and
a cover substrate on the display panel,
wherein the cover substrate includes a plurality of concave portions and a plurality of convex portions that are alternately disposed, and
wherein the cover substrate has an arithmetic mean roughness (Ra) of 0.25 μm or less and an average width (Rsm) of 10 μm or less.

15. The display device of claim 14,
wherein a pixel of the pixels includes a plurality of sub-pixels having different light-emitting portions, and
wherein, in a plan view, the light-emitting portions of the plurality of sub-pixels are each formed in a circular shape.

16. The display device of claim 15,
wherein the plurality of sub-pixels includes a first sub-pixel configured to emit red light, a second sub-pixel configured to emit green light, and a third sub-pixel configured to emit blue light,
wherein the first sub-pixel includes a first light-emitting portion,
wherein the second sub-pixel includes a second light-emitting portion,
wherein the third sub-pixel includes a third light-emitting portion,
wherein a diameter of the third light-emitting portion is larger than a diameter of the second light-emitting portion, and
wherein the diameter of the second light-emitting portion is larger than a diameter of the first light-emitting portion.

17. The display device of claim 14,
wherein the cover substrate has a root mean square height (Sq) of 0.4 μm or less.

18. The display device of claim 14,
wherein the cover substrate has a maximum height (Sz) of 10.0 μm or less.

19. The display device of claim 14,
wherein the cover substrate has a root mean square gradient (Sdq) in a range of 0.15 to 0.30.

20. The display device of claim 14,
wherein the cover substrate has an arithmetic mean peak curvature (Spc) in a range of 0.5 to 3.0.
